(19) United States
(12) Patent Application Publication
(10) Pub. No.: US 2024/0178086 A1
(43) Pub. Date: May 30, 2024

(54) PACKAGE, PACKAGE STRUCTURE AND METHOD OF MANUFACTURING PACKAGE STRUCTURE

(71) Applicant: Taiwan Semiconductor Manufacturing Company, Ltd., Hsinchu (TW)

(72) Inventors: Che-Yu Yeh, New Taipei City (TW); Chien-Chia Chiu, Taoyan City (TW); Hua-Wei Tseng, New Taipei City (TW); Wan-Yu Lee, Taipei City (TW)

(73) Assignee: Taiwan Semiconductor Manufacturing Company, Ltd., Hsinchu (TW)

(21) Appl. No.: 18/169,177

(22) Filed: Feb. 14, 2023

Related U.S. Application Data
(60) Provisional application No. 63/427,900, filed on Nov. 24, 2022.

(51) Int. Cl. H01L 23/24; H01L 21/56; H01L 23/00; H01L 23/31; H01L 25/00; H01L 25/10; H01L 25/16

(52) U.S. Cl. CPC H01L 23/24; H01L 21/568; H01L 23/3121; H01L 24/24; H01L 25/105; H01L 25/16; H01L 25/50; H01L 24/48; H01L 2224/24101; H01L 2224/24155; H01L 2224/48228; H01L 2225/1023; H01L 2225/1058; H01L 2924/19011; H01L 2924/19041; H01L 2924/19042; H01L 2924/19043

(57) ABSTRACT

Disclosed are a package, a package structure and a method of manufacturing a package structure. In one embodiment, the package includes a die, a plurality of through vias, at least one dummy structure, an encapsulant and a redistribution structure. The plurality of through vias surround the die. The at least one dummy structure is disposed between the die and the plurality of through vias and adjacent to at least one corner of the die. The encapsulant encapsulates the die, the plurality of through vias and the at least one dummy structure. The redistribution structure is disposed on the die, the plurality of through vias, the at least one dummy structure and the encapsulant and electrically connected to the die and the plurality of through vias.

### CROSS-REFERENCE TO RELATED APPLICATION

This application claims the priority benefit of U.S. provisional application Ser. No. 63/427,900, filed on Nov. 24, 2022. The entirety of the above-mentioned patent application is hereby incorporated by reference herein and made a part of this specification.

### BACKGROUND

Semiconductor devices and integrated circuits used in a variety of electronic applications, such as cell phones and other mobile electronic equipment, are typically manufactured on a single semiconductor wafer. The dies of the wafer may be processed and packaged with other semiconductor devices or dies at the wafer level, and various technologies have been developed for the wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1G are schematic cross-sectional views illustrating a process flow for manufacturing a package structure in accordance with some embodiments of the present disclosure.

FIG. 2 through FIG. 10 are schematic partial top views illustrating various arrangements of a package in accordance with some embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

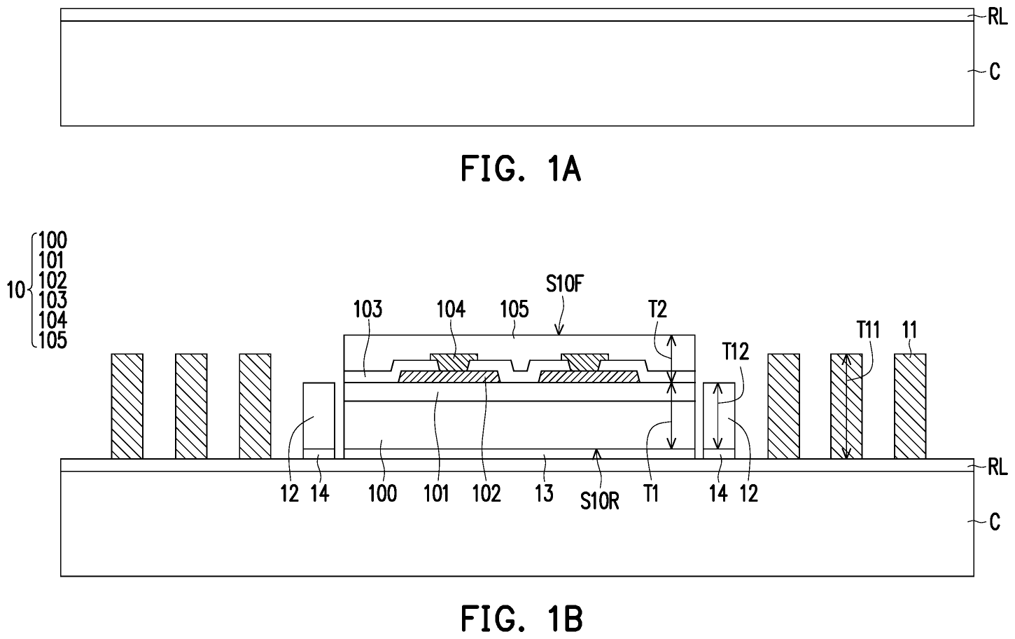

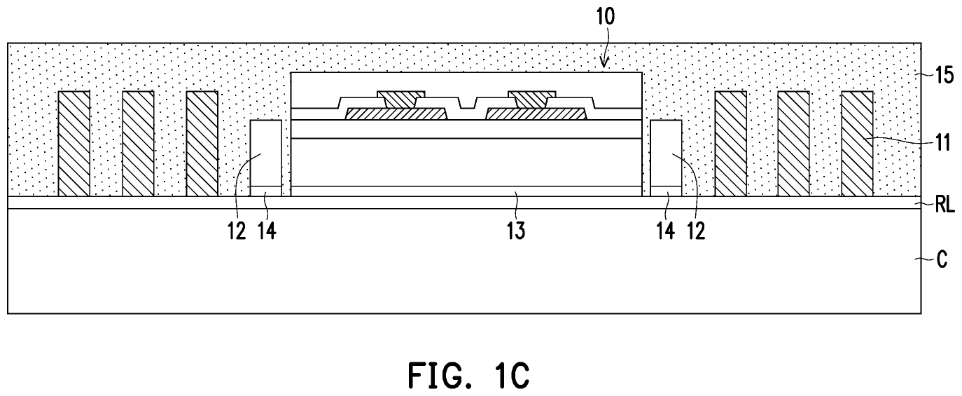

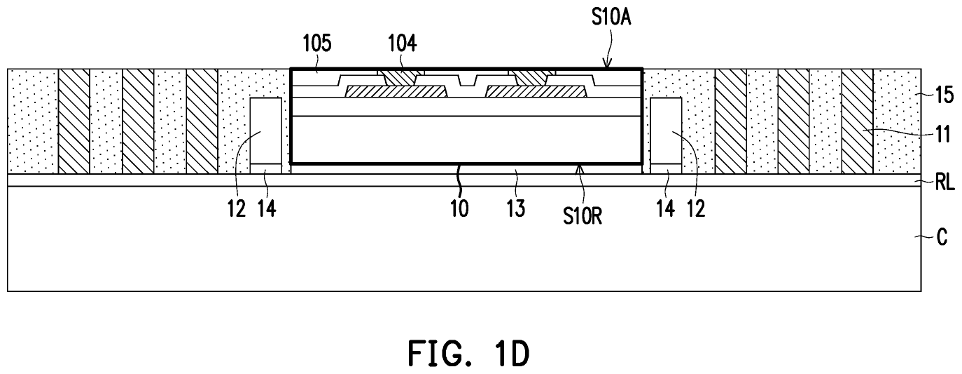

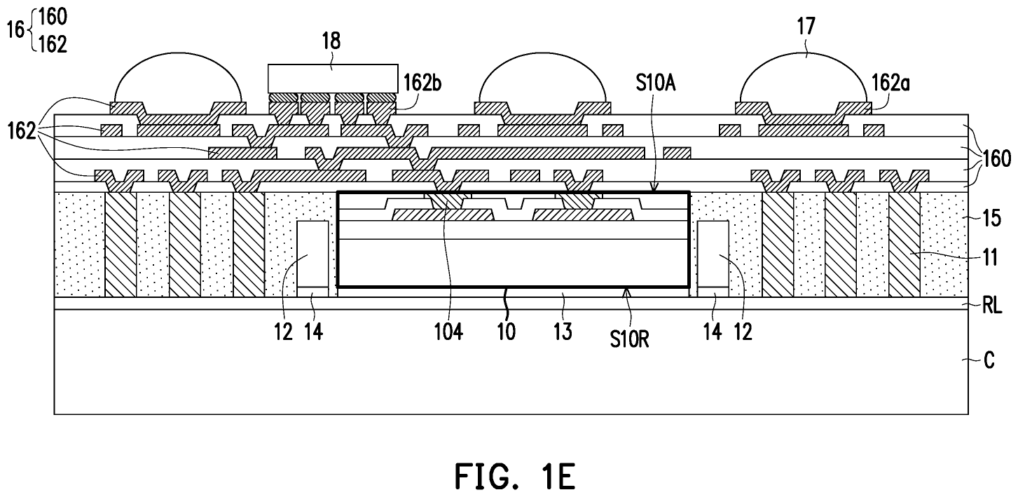

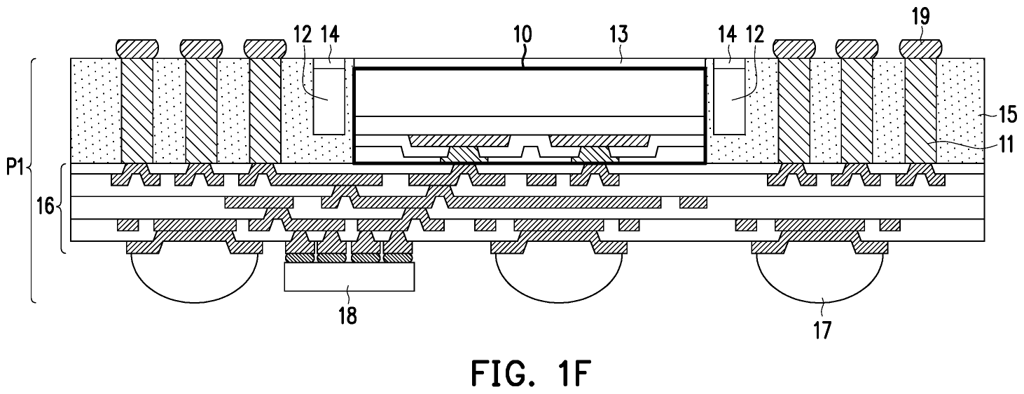

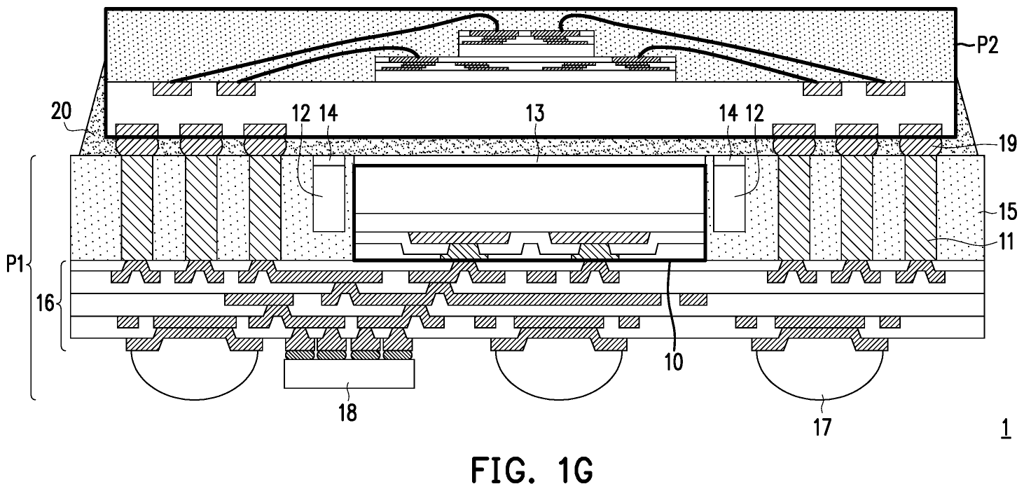

FIG. 1A through FIG. 1G are schematic cross-sectional views illustrating a process flow for manufacturing a package structure in accordance with some embodiments of the present disclosure.

Referring to FIG. 1A, a carrier substrate (or referred to as a substrate) C is provided. The carrier substrate C may be a glass carrier substrate, a ceramic carrier substrate, or the like. The carrier substrate C may be a wafer, such that multiple packages may be formed on the carrier substrate C simultaneously.

In some embodiments, a release layer RL is formed on the carrier substrate C. The release layer RL may be formed of a polymer-based material, which may be removed along with the carrier substrate C from the overlying structures that will be formed in subsequent steps. In some embodiments, the release layer RL is an epoxy-based thermal-release material, which loses its adhesive property when heated, such as a light-to-heat-conversion (LTHC) release coating. In other embodiments, the release layer RL may be an ultra-violet (UV) glue, which loses its adhesive property when exposed to UV lights. The release layer RL may be dispensed as a liquid and cured, may be a laminate film laminated onto the carrier substrate C, or may be the like. The top surface of the release layer RL may be leveled and may have a high degree of planarity.

In some embodiments, although not shown, a dielectric layer is formed on the release layer RL. In some embodiments, the dielectric layer is formed of a polymer, such as polybenzoxazole (PBO), polyimide (PI), benzocyclobutene (BCB), or the like. In other embodiments, the dielectric layer is formed of a nitride such as silicon nitride; an oxide such as silicon oxide, phosphosilicate glass (PSG), borosilicate glass (BSG), boron-doped phosphosilicate glass (BPSG), or the like. The dielectric layer may be formed by any acceptable deposition process, such as spin coating, chemical vapor deposition (CVD), laminating, the like, or a combination thereof. In some embodiments, the dielectric layer has adhesion property to adhere the subsequently formed elements.

Referring to FIG. 1B, a die 10, a plurality of through vias (or referred to as conductive vias or conductive pillars) 11 and at least one dummy structure 12 are formed on the carrier C, and the release layer RL is located between the die 10 and the carrier C, between the plurality of through vias 11 and the carrier C and between the at least one dummy structure 12 and the carrier C.

In some embodiments, the die 10 is picked and placed onto the release layer RL (or the dielectric layer if existed). Although one die 10 is illustrated in FIG. 1B, it construes no limitation in the disclosure. In some alternative embodiments, more than one dies 10 may be picked and placed onto the release layer RL (or the dielectric layer if existed). The dies 10 may be logic dies (e.g., central processing unit, microcontroller, etc.), memory dies (e.g., dynamic random access memory (DRAM) die, static random access memory (SRAM) die, etc.), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof.

Before being adhered to the release layer RL (or the dielectric layer if existed), the die(s) 10 may be processed according to applicable manufacturing processes to form integrated circuits in the die(s) 10. For example, the die 10 includes a semiconductor substrate 100, such as silicon, doped or undoped, or an active layer of a semiconductor-on-insulator (SOI) substrate. The semiconductor substrate 100 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Devices, such as transistors, diodes, capacitors, resistors, inductors, etc., may be formed in and/or on the semiconductor substrate 100 and may be interconnected by an interconnect structure 101 formed by, for example, metallization patterns in one or more dielectric layers on the semiconductor substrate 100 to form an integrated circuit.

The die 10 further includes a plurality of conductive pads 102 disposed over the interconnect structure 101. The conductive pads 102 may be aluminum pads, copper pads, or other suitable metal pads.

The die 10 further includes a passivation layer 103 formed over the interconnect structure 101. The passivation layer 103 has contact openings that partially expose the conductive pads 102. The passivation layer 103 may be a silicon oxide layer, a silicon nitride layer, a silicon oxy-nitride layer, or a dielectric layer formed by other suitable dielectric materials.

The die 10 further includes a plurality of conductive vias 104 formed on and electrically coupled to the conductive pads 102. The conductive vias 104 includes a metal such as copper, and the conductive vias 104 are formed by, for example, plating, or the like.

The die 10 further includes a s formed on the passivation layer 103 to cover the conductive vias 104. The protection layer 105 may be a polymer such as PBO, polyimide, BCB, or the like; a nitride such as silicon nitride or the like; an oxide such as silicon oxide, PSG, BSG, BPSG, or the like; the like, or a combination thereof, and may be formed, for example, by spin coating, lamination, CVD, or the like.

In some embodiments, although not shown, a post-passivation layer is formed over the passivation layer 103 prior to forming the conductive vias 104 and the protection layer 105. The post-passivation layer covers the passivation layer 103 and has a plurality of contact openings that overlap the contact openings of the passivation layer 103 and thus partially expose the conductive pads 102. The post-passivation layer may be a PI layer, a PBO layer, or a dielectric layer formed by other suitable polymers. The protection layer 105 is formed on the post-passivation layer to cover the conductive vias 104.

As illustrated in FIG. 1B, the die 10 has a rear surface S10R and a front surface S10F opposite to the rear surface S10R. In some embodiments, the rear surface S10R of the die 10 is attached (or adhered) to the release layer RL (or the dielectric layer if existed) through a first attach film 13, such as a die attach film (DAF), any suitable adhesive film, epoxy film, or the like. On the other hand, the front surface S10F of the die 10 faces upward and is exposed.

The plurality of through vias 11 are formed to surround the die 10. Although six through vias 11 are illustrated in FIG. 1B, it construes no limitation in the disclosure. In some alternative embodiments, more than six through vias 11 may be formed onto the release layer RL (or the dielectric layer if existed). In some embodiments, the plurality of through vias 11 are formed on the release layer RL (or the dielectric layer if existed) prior to attaching (or adhering) the die 10 to the release layer RL (or the dielectric layer if existed), but not limited thereto.

In some embodiments, the method of forming the plurality of through vias 11 includes the following steps. First, a seed material layer (not shown) is formed over the release layer RL (or the dielectric layer if existed). In some embodiments, the seed material layer includes a titanium/copper composite layer formed by a physical vapor deposition (PVD) process (e.g., a sputtering process) or the like. Subsequently, a photoresist layer (not shown) is formed and patterned on the seed material layer. The photoresist layer may be formed by spin coating or the like and may be exposed to light for patterning. The patterning forms openings of the photoresist layer. The openings of the photoresist layer expose the intended locations for the subsequently formed through vias 11. Thereafter, a plating process (such as electroplating, electroless plating, or the like) is performed to form a metal material (e.g., copper, titanium, tungsten, aluminum, or the like) layer on the seed material layer exposed by the openings of the photoresist layer. The photoresist layer and the underlying seed material layer are then removed to form the plurality of through vias 11. The photoresist layer may be removed by an acceptable ashing or stripping process, such as using an oxygen plasma or the like, for example. The underlying seed material layer may be removed by using an acceptable etching process, such as by a wet or a dry etching process. However, the disclosure is not limited thereto. In some alternative embodiments, the plurality of through vias 11 may be formed by pick and place pre-fabricated conductive structures onto the release layer RL (or the dielectric layer if existed).

The at least one dummy structure 12 is formed to surround the die 10 and to be disposed between the die 10 and the plurality of through vias 11 and adjacent to at least one corner of the die 10. For example, the number of the at least one dummy structure 12 is a multiple of four (e.g., 4, 8 or more), and the multiple of four dummy structures 12 are disposed adjacent to four corners of the die 10. Alternatively, the number of the at least one dummy structure 12 is one, and the dummy structure 12 is a ring structure surrounding the die 10. Although two dummy structures 12 are illustrated in FIG. 1B, it construes no limitation in the disclosure. In some alternative embodiments, other number of dummy structures 12 may be picked and placed onto the release layer RL (or the dielectric layer if existed).

In some embodiments, the at least one dummy structure 12 is picked and placed onto the release layer RL (or the dielectric layer if existed). In some embodiments, the at least one dummy structure 12 is attached (or adhered) to the release layer RL (or the dielectric layer if existed) through at least one second attach film 14, such as at least one die attach film (DAF), any suitable adhesive film, epoxy film, or the like. For example, each dummy structure 12 is attached (or adhered) to the release layer RL (or the dielectric layer if existed) through a corresponding second attach film 14.

The at least one dummy structure 12 is configured to improve delamination of the dielectric layer(s) in the die 10 and/or RDL (redistribution structure) crack that are caused by thermal expansion and contraction of an encapsulant 15 (see FIG. 1C) subsequently formed to encapsulate the die 10, the plurality of through vias 11 and the at least one dummy structure 12. In some embodiments, Young's modulus of the at least one dummy structure 12 is greater than 10 GPa, and coefficient of thermal expansion (CTE) of the at least one dummy structure 12 is less than 44 ppm/° C. to. For example, a material of the at least one dummy structure 12 includes silicon, germanium, silicon germanium, silicon carbide, gallium arsenic, gallium phosphide, indium phosphide, indium arsenide, indium antimonide, GaAsP, AlInAs, AlGaAs, GaInAs, GaInP, GaInAsP, combinations thereof, cupper, or any other material that has higher hardness and lower CTE than that of the encapsulant 15 (see FIG. 1C).

In some embodiments, a thickness T11 of the at least one dummy structure 12 is smaller than a thickness T12 of the plurality of through vias 11. In some embodiments, the thickness T12 of the at least one dummy structure 12 is equal to or greater than a total thickness T1 of the semiconductor substrate 100 and the interconnect structure 101 of the die 10 and equal to or smaller than a total thickness (i.e., T1+T2) of the die 10. In some embodiments, a total thickness T2 of the layers other than the semiconductor substrate 100 and the interconnect structure 101 in the die 10 is 20 μm, and T12≤(T1+20) μm.

Referring to FIG. 1C, the encapsulant 15 is formed to laterally encapsulates the die 10, the plurality of through vias 11 and the at least one dummy structure 12. In some embodiments, the encapsulant 15 includes a molding compound, a molding underfill, a resin such as epoxy, a combination thereof, or the like. In some other embodiments, the encapsulant 15 includes a photo-sensitive material such as polybenzoxazole (PBO), polyimide (PI), benzocyclobutene (BCB), a combination thereof, or the like, which may be easily patterned by exposure and development processes or laser drilling process. In alternative embodiments, the encapsulant 15 includes nitride such as silicon nitride, oxide such as silicon oxide, phosphosilicate glass (PSG), borosilicate glass (BSG), boron-doped phosphosilicate glass (BPSG), a combination thereof, or the like. The encapsulant 15 may be applied by compression molding, transfer molding, spin-coating, lamination, deposition, or similar processes, and may be formed over the carrier substrate C such that the die 10, the plurality of through vias 11 and the at least one dummy structure 12 are buried or covered. The encapsulant 15 is then cured.

Referring to FIG. 1D, a planarization process is then performed on the encapsulant 15 to remove a portion of the encapsulant 15, such that the top surfaces of the plurality of conductive vias 104 and the plurality of through vias 11 are exposed. In some embodiments which the top surfaces of the plurality of conductive vias 104 and the front surface S10F of the die 10 are not coplanar (as shown in FIG. 1), portions of the protection layer 105 or/and portions of the plurality of conductive vias 104 may also be removed by the planarization process. In some embodiments which the top surfaces of the plurality of through vias 11 are higher than the top surfaces of the plurality of conductive vias 104 (as shown in FIG. 1i), portions of the plurality of through vias 11 may also be removed by the planarization process. In some embodiments, top surfaces of the plurality of conductive vias 104, the plurality of through vias 11, the protection layer 105, and the encapsulant 15 are substantially coplanar after the planarization process. The planarization process may be, for example, a chemical-mechanical polish (CMP), a grinding process, or the like. In some embodiments, the planarization may be omitted, for example, if the plurality of conductive vias 104 and the plurality of through vias 11 are already exposed. The plurality of through vias 11 penetrate the encapsulant 15, and the plurality of through vias 11 are sometimes referred to as through integrated fan-out vias (TIVs). After the planarization process, the top surface of the die 10 exposing the plurality of conductive vias 104 is sometimes referred to as the active surface S10A of the die 10.

Referring to FIG. 1E, a redistribution structure 16 electrically connected to the the die 10 and the plurality of through vias 11 is formed on the die 10, the plurality of through vias 11, the at least one dummy structure 12 and the encapsulant 15. For example, the redistribution structure 16 is formed on the active surface S10A of the die 10, such that the first attach film 13 and the redistribution structure 16 are respectively located on opposite sides of the die 10, and the at least one second attach film 14 and the redistribution structure 16 are respectively located on opposite sides of the at least one dummy structure 12.

In some embodiments, the redistribution structure 16 includes a plurality of inter-dielectric layers 160 and a plurality of redistribution conductive layers (may also be referred to as redistribution layers or redistribution lines) 162 stacked alternately. The redistribution conductive layers 162 are electrically connected to the plurality of conductive vias 104 of the die 10 and the plurality of through vias 11 embedded in the encapsulant 15. In some embodiments, the top surfaces of the plurality of conductive vias 104 and the top surfaces of the plurality of through vias 11 are in contact with the bottommost redistribution conductive layer 162 of the redistribution structure 16. In some embodiments, the top surfaces of the plurality of conductive vias 104 and the top surfaces of the plurality of through vias 11 are partially covered by the bottommost inter-dielectric layer 160. As illustrated in FIG. 1E, the topmost redistribution conductive layer 162 includes a plurality of pads. In some embodiments, the above-mentioned pads include a plurality of under-ball metallurgy (UBM) patterns 162a for ball mount and/or at least one connection pads 162b for mounting of passive components (such as integrated passive devices (IPD)). The number of the inter-dielectric layers 160 and the redistribution conductive layers 162 is not limited in the disclosure. In some embodiments, the configurations of the UBM patterns 162a and the connection pads 162b may be determined based on circuit design.

The plurality of inter-dielectric layers 160 and the plurality of redistribution conductive layers 162 are alternately formed. In some embodiments, the inter-dielectric layer 160 is formed of a photo-sensitive material such as PBO, polyimide, BCB, or the like, which may be patterned using a lithography mask. The inter-dielectric layer 160 may be formed by spin coating, lamination, CVD, the like, or a combination thereof. The inter-dielectric layer 160 is then patterned. The patterning forms via openings (not shown) exposing portions of the plurality of conductive vias 104, portions of the plurality of through vias 11 or exposing portions of the redistribution conductive layers 162. The patterning may be by an acceptable process, such as by exposing the inter-dielectric layer 160 to light when the inter-dielectric layer 160 is a photo-sensitive material or by etching using, for example, an anisotropic etch. If the inter-dielectric layer 160 is a photo-sensitive material, the inter-dielectric layer 160 may be developed after the exposure.

In some embodiments, the method of forming the redistribution conductive layers 162 includes the following steps. First, a seed material layer (not shown) is formed over the inter-dielectric layer 160 and in the via openings extending through the inter-dielectric layer 160. In some embodiments, the seed material layer includes a titanium/copper composite layer formed by a physical vapor deposition (PVD) process (e.g., a sputtering process) or the like. Subsequently, a photoresist layer (not shown) is formed and patterned on the seed material layer. The photoresist layer may be formed by spin coating or the like and may be exposed to light for patterning. The patterning forms openings of the photoresist layer. The openings of the photoresist layer expose the intended locations for the subsequently formed metal material layer. Thereafter, a plating process (such as electroplating, electroless plating, or the like) is performed to form the metal material (e.g., copper, titanium, tungsten, aluminum, or the like) layer on the seed material layer exposed by the openings of the photoresist layer. The photoresist layer and the underlying seed material layer are then removed to form the redistribution conductive layers 162. The photoresist layer may be removed by an acceptable ashing or stripping process, such as using an oxygen plasma or the like, for example. The underlying seed material layer may be removed by using an acceptable etching process, such as by a wet or a dry etching process. However, the disclosure is not limited thereto.

After the redistribution structure 16 is formed, a plurality of conductive terminals 17 are disposed on and electrically connected to the redistribution structure 16. For example, the plurality of conductive terminals 17 are placed on the UBM patterns 162a. In some embodiments, the conductive terminal 17 includes ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the conductive terminals 17 may be placed on the UBM patterns 162a through a ball placement process. In other embodiments, the conductive terminals 17 may be formed on the UBM patterns 162a by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In another embodiment, the conductive terminals 17 may include a conductive material such as solder, copper, aluminum, gold, nickel, silver, palladium, tin, the like, or a combination thereof. In some embodiments, the conductive terminals 17 are formed by initially forming a layer of solder through such commonly used methods such as evaporation, electroplating, printing, solder transfer, ball placement, or the like. Once a layer of solder has been formed on the structure, a reflow process may be performed in order to shape the material into the desired bump shapes.

After the redistribution structure 16 is formed, a passive component (such as an integrated passive device) 18 is disposed on and electrically connected to the redistribution structure 16, wherein the passive component 18 and the die 10 are located on opposite sides of the redistribution structure 16, respectively. For example, the passive component 18 is mounted on the connection pads 162b. The passive component 18 is, for example, a capacitor, a resistor, an inductor, an antenna, the like, or a combination thereof. In some embodiments, the passive component 18 may be mounted on the connection pads 162b through a soldering process and/or a reflowing process. Although one passive component 18 is illustrated in FIG. 1F, it construes no limitation in the disclosure. In some alternative embodiments, more than one passive components 18 may be mounted on the connection pads 162b.

Referring to FIG. 1F, after the conductive terminals 17 and the passive component 18 are mounted on the redistribution structure 16, a carrier substrate de-bonding process is performed to detach (or “de-bond”) the carrier substrate C from the encapsulant 15 (or the dielectric layer (if existed) formed between the encapsulant 15 and the release layer RL) to form a package (e.g., a first package P1). In some embodiments, the de-bonding process includes projecting a light such as a laser light or an UV light on the release layer RL so that the release layer RL decomposes under the heat of the light and the carrier substrate C may be removed.

The first package P1 is then flipped over and placed on a tape (not shown). Thereafter, joint terminals 19 are formed on and electrically connect to the plurality of through vias 11. In some embodiments, the joint terminals 19 may be formed in a manner similar to the conductive terminals 17, and may be formed of the same material as the conductive terminals 17. In other embodiments, although not shown, the joint terminals 19 are electrically connected to the plurality of through vias 11 through a back-side redistribution structure. The back-side redistribution structure may be formed in a manner similar to the redistribution structure 16, and may be formed of the same material as the redistribution structure 16. More or fewer inter-dielectric layers and redistribution conductive layers may be formed in the back-side redistribution structure.

In some embodiments which the dielectric layer is formed between the encapsulant 15 and the release layer RL, the dielectric layer is patterned (e.g., by a laser drilling process) to form a plurality of openings, and the plurality of through vias 11 are at least partially exposed by the plurality of openings. Then, the joint terminals 19 are formed in the plurality of openings of the dielectric layer. For example, a conductive paste (such as a solder paste or other suitable paste) may be filled into the plurality of openings of the dielectric layer and then cured by, for example, a reflowing process to form the joint terminals 19.

Referring to FIG. 1G, a second package P2 is stacked on the first package P1 to obtain a package-on-package (PoP) structure 1, wherein the second package P2 is electrically connected to the first package P1 through the joint terminals 19. In some embodiments, the first package P1 may include an InFO package or other types of packages. In some embodiments, the second package P2 is, for example, a memory device or other IC packages. In some embodiments, after the second package P2 is stacked on the first package P1, a reflowing process is further performed.

In some embodiments, an underfill 20 is formed between the second package P2 and the first package P1. The underfill 20 fills a gap between the second package P2 and the first package P1 to encapsulate the joint terminals 19. The joint terminals 19 are laterally encapsulated and protected by the underfill 20 such that damage of the joint terminals 19 resulted from coefficient of thermal expansion (CTE) mismatch between the second package P2 and the first package P1 may be prevented or alleviated. Accordingly, reliability of the joint terminals 19 may be improved.

A reliability test (e.g., a board level reliability test) is performed after the second package P2 is stacked on the first package P1. During the reliability test, temperature and/or humidity is/are raised, and the components (e.g., the die 10, the encapsulant 15 and the redistribution structure 16) of the package structure 1 expand/swell due to heat and/or moisture. Since the encapsulant 15 has smaller Young's modulus and larger CTE than the die 10 and the redistribution structure 16, tensile stress in the longitudinal direction (e.g., a thickness direction of the package structure 1) is easily generated between the encapsulant 15 and the die 10, and tensile stress in the transverse direction (e.g., a direction parallel to the package structure 1) is easily generated between the encapsulant 15 and the redistribution structure 16. As a result, delamination of the dielectric layer(s) in the die 10 and/or RDL (redistribution structure 16) crack tend to occur near corners of the die 10. In the embodiments, at least one dummy structure 12 is provided adjacent to at least one corner of the die 10 to reduce the tensile stress generated between the encapsulant 15 and the die 10 and between the encapsulant 15 and the redistribution structure 16 by reducing the amount of the encapsulant 15. In this way, delamination of the dielectric layer(s) in the die 10 and/or RDL (redistribution structure) crack can be improved.

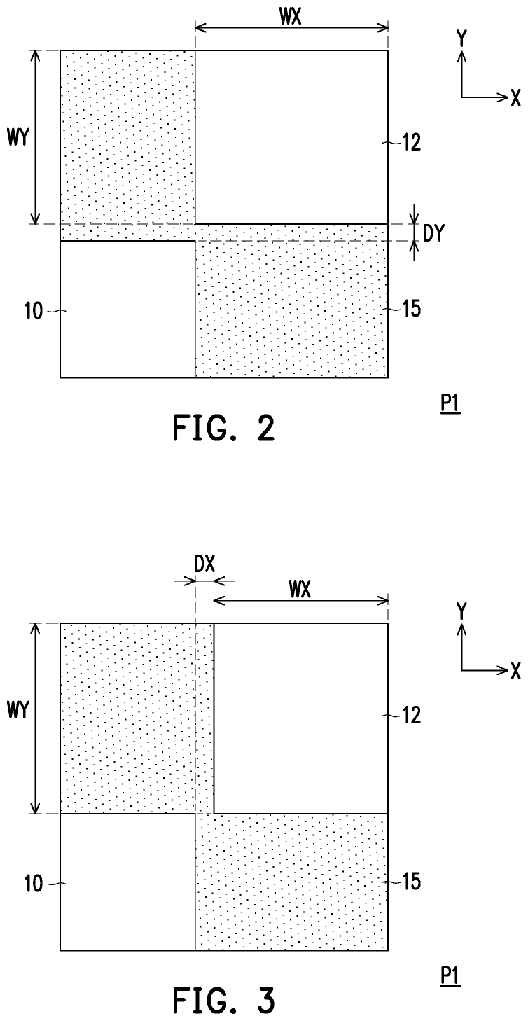

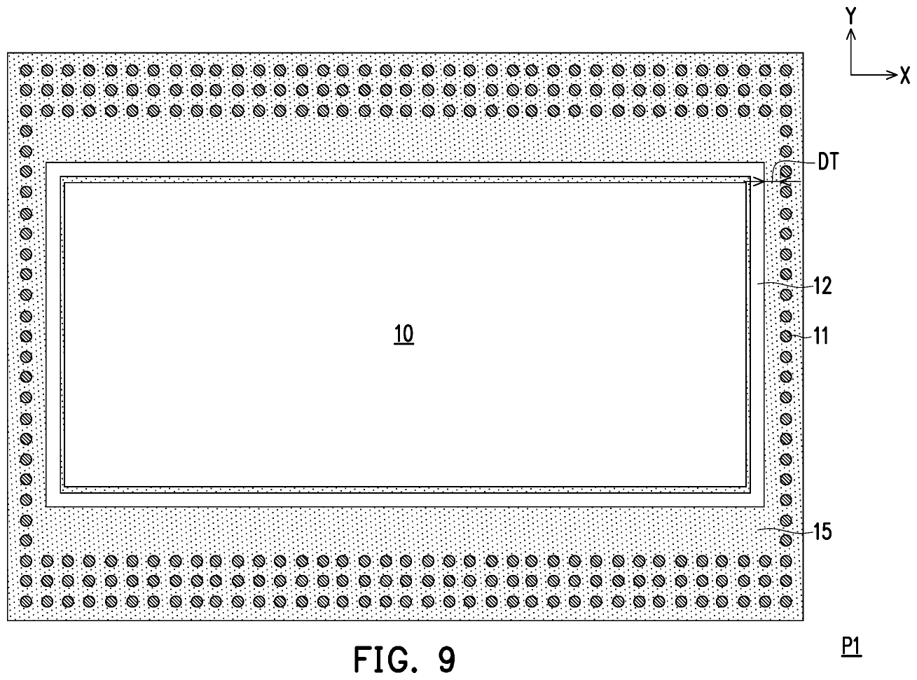

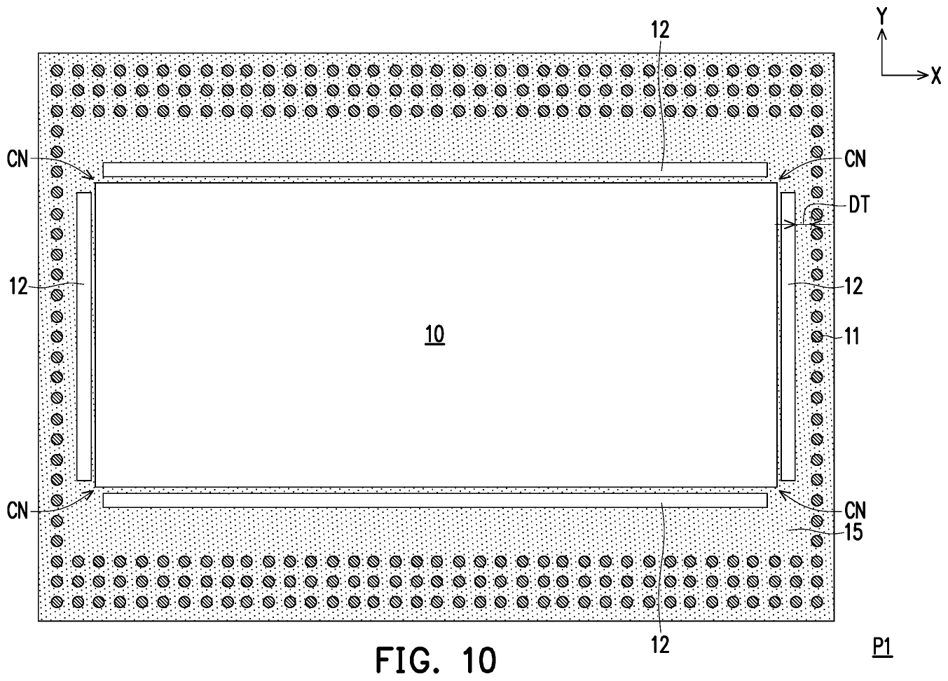

FIG. 2 through FIG. 10 are schematic partial top views illustrating various arrangements of a package (first package P1) in accordance with some embodiments of the present disclosure. For the brevity of the drawings, FIG. 2 to FIG. 8 schematically illustrate the upper right corner of the die 10, the dummy structure(s) 12 located at the upper right corner of the die 10, and the encapsulant 15 overlapping the above two, and remaining components of the first package P1 are omitted from the drawings. It should be understood that the four corners of die 10 may have corresponding dummy structures 12, but the disclosure is not limited thereto. For example, the dummy structures 12 respectively located at the four corners of the die 10 may have other designs (e.g., different relative dispositions, different numbers and/or different sizes). Further, for the same purpose, FIG. 9 and FIG. 10 schematically illustrate the die 10, the dummy structure(s) 12 and the plurality of through vias 11, and remaining components of the first package P1 are omitted from the drawings. It should be understood that the relative disposition among the die 10, the dummy structure(s) 12 and the plurality of through vias 11; the number of each of the die 10, the dummy structure(s) 12 and the plurality of through vias 11; and/or the size of each of the die 10, the dummy structure(s) 12 and the plurality of through vias 11 may be altered according to different needs.

In some embodiments, based on considerations such as process and reliability, a distance between the dummy structure 12 and the die 10 is equal to or greater than 60 μm and less than 300 μm.

For example, as shown in FIG. 2, a distance DY between the dummy structure 12 and the die 10 along a direction Y (may also referred to as a second direction) is equal to or greater than 60 μm and less than 300 μm. Further, a distance DX (not show in FIG. 2, please refer to FIG. 3) between the dummy structure 12 and the die 10 along a direction X (may also referred to as a first direction) may be equal to zero. A width of the dummy structure 12 along a first direction (i.e., the direction X) is WX, and a width of the dummy structure 12 along a second direction (i.e., the direction Y) is WY. In some embodiments, WX=300 μm, and (WY+DY)=300 μm.

As shown in FIG. 3, the distance DX between the dummy structure 12 and the die 10 along the direction X is equal to or greater than 60 μm and less than 300 μm. Further, the distance DY (not show in FIG. 3, please refer to FIG. 2) between the dummy structure 12 and the die 10 along the direction Y may be equal to zero. In some embodiments, (WX+DX)=300 μm, and WY=300 μm.

As shown in FIG. 4, each of the distance DX and the distance DY is equal to or greater than 60 μm and less than 300 μm. In some embodiments, (WX+DX)=300 μm, and (WY+DY)=300 μm.

In some embodiments, 0.33*WX≤WY≤3*WX or 0.33*WY≤WX≤3*WY for ease of manufacture (e.g., to facilitate adsorption of a transfer head (not shown)).

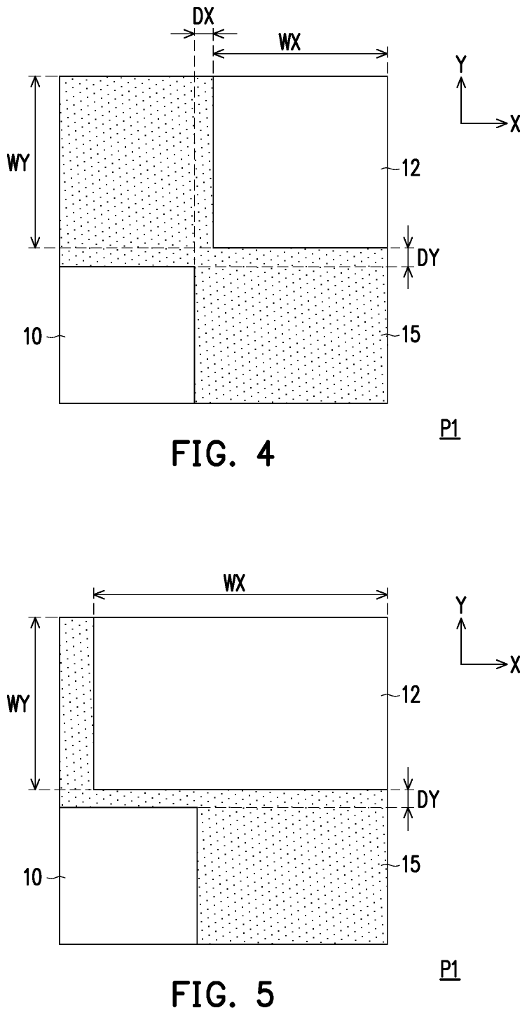

For example, as shown in FIG. 5, 300 μm≤WX<3*WY, (WY+DY)=300 μm, and 60 μm≤DY<300 μm. In other embodiments, although not shown in FIG. 5, please refer to the dummy structure 12a in FIG. 7, (WYa+DY)≥300 μm, and 0.33*WXa≤WYa≤3*WXa.

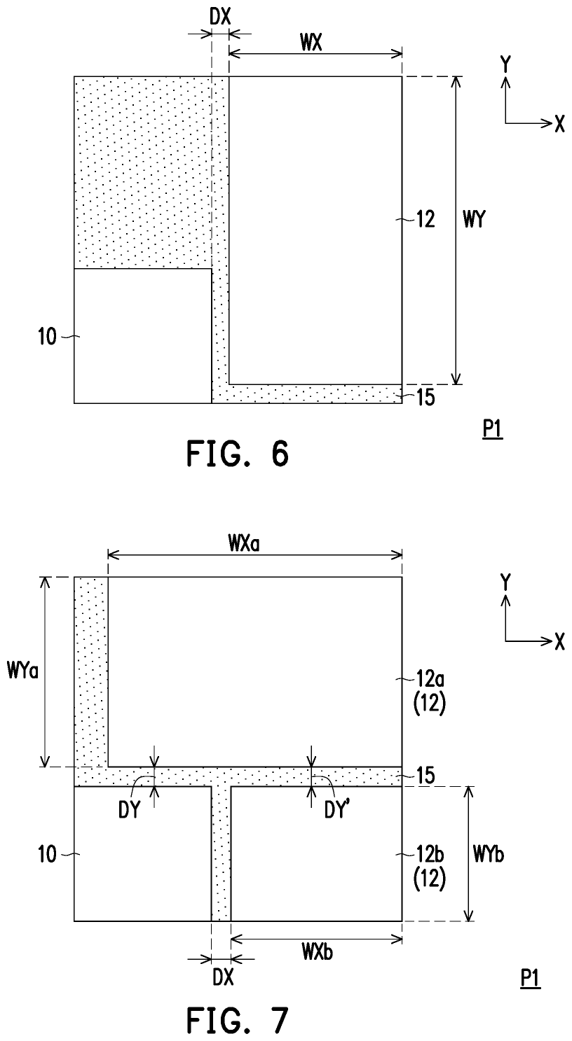

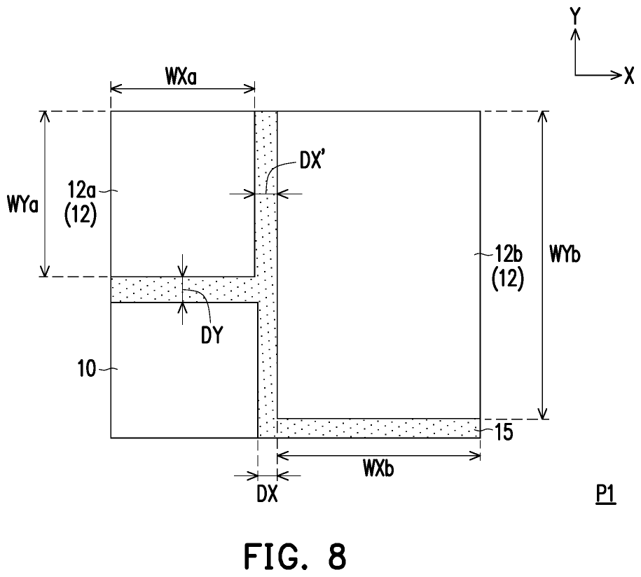

As shown in FIG. 6, 300 μm≤WY<3*WX, (WX+DX)=300 μm, and 60 μm≤DX<300 μm. In other embodiments, although not shown in FIG. 6, please refer to the dummy structure 12b in FIG. 8, (WXb+DX)≥300 μm, and 0.33*WYb≤WXb≤3*WYb.

In some embodiments, more than one dummy structures 12 are disposed adjacent to one corner of the die 10.

For example, as shown in FIG. 7, two dummy structures 12 (e.g., a dummy structures 12a and a dummy structures 12b) are disposed adjacent to the upper right corner of the die 10, wherein the dummy structures 12a is spaced apart from the die 10 by the distance DY, the dummy structures 12b is spaced apart from the die 10 by the distance DX, and the dummy structures 12b is spaced apart from the dummy structures 12a by a distance DY′ along the direction Y. Each of the distance DX, the distance DY and the distance DY′ may be equal to or greater than 60 μm and less than 300 μm.

In some embodiments, for the dummy structures 12a, (WYa+DY)≥300 μm, and 0.33*WXa≤WYa≤3*WXa. In some embodiments, for the dummy structures 12b, (WXb+DX)≥300 μm, and 0.33*WXb≤WYb≤3*WXb.

As shown in FIG. 7, the dummy structures 12b is spaced apart from the dummy structures 12a by a distance DX′ along the direction X. Each of the distance DX, the distance DY and the distance DX′ may be equal to or greater than 60 μm and less than 300 μm.

In some embodiments, for the dummy structures 12b, (WXb+DX)≥300 μm, and 0.33*WYb≤WXb≤3*WYb. In some embodiments, for the dummy structures 12a, (WYa+DY)≥300 μm, and 0.33*WYa≤WXa≤3*WYa.

As shown in FIG. 9, the number of the at least one dummy structure 12 of the first package P1 may be one, and the dummy structure 12 may be a ring structure surrounding the die 10. In some embodiments, based on considerations such as process and reliability, a distance DT (e.g., a minimum distance along the direction X or the direction Y) between the dummy structure 12 and an adjacent through via 11 among the plurality of through vias 11 is equal to or greater than 300 μm.

As shown in FIG. 10, the number of the at least one dummy structure 12 of the first package P1 may be four, and the four dummy structures 12 may be disposed adjacent to four corners CN of the die 10. For example, each of the four dummy structures 12 may be disposed adjacent to a corresponding side of the die 10 and extending toward two corresponding corners CN of the die 10.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the present disclosure, a package includes a die, a plurality of through vias, at least one dummy structure, an encapsulant and a redistribution structure. The plurality of through vias surround the die. The at least one dummy structure is disposed between the die and the plurality of through vias and adjacent to at least one corner of the die. The encapsulant encapsulates the die, the plurality of through vias and the at least one dummy structure. The redistribution structure is disposed on the die, the plurality of through vias, the at least one dummy structure and the encapsulant and electrically connected to the die and the plurality of through vias. In some embodiments, Young's modulus of the at least one dummy structure is greater than 10 GPa, and coefficient of thermal expansion of the at least one dummy structure is less than 44 ppm/° C. In some embodiments, a number of the at least one dummy structure is a multiple of four, and the multiple of four dummy structures are disposed adjacent to four corners of the die. In some embodiments, a number of the at least one dummy structure is one, and the dummy structure is a ring structure surrounding the die. In some embodiments, the package further includes a first attach film disposed on the die and at least one second attach film disposed on the at least one dummy structure, wherein the first attach film and the redistribution structure are respectively located on opposite sides of the die, and the at least one second attach film and the redistribution structure are respectively located on opposite sides of the at least one dummy structure. In some embodiments, a thickness of the at least one dummy structure is smaller than a thickness of the plurality of through vias. In some embodiments, a distance between the at least one dummy structure and the die is equal to or greater than 60 μm and less than 300 μm. In some embodiments, a width of the at least one dummy structure along a first direction is WX, a width of the at least one dummy structure along a second direction is WY, and the package satisfies one of the following: 0.33*WX WY 3*WX; and 0.33*WY≤WX≤3*WY. In some embodiments, a distance between the at least one dummy structure and an adjacent through via among the plurality of through vias is equal to or greater than 300 μm.

In accordance with some embodiments of the present disclosure, a package structure includes a first package, a plurality of joint terminals and a second package. The first package includes a die, a plurality of through vias, at least one dummy structure, an encapsulant and a redistribution structure. The plurality of through vias surround the die. The at least one dummy structure is disposed between the die and the plurality of through vias and adjacent to at least one corner of the die. The encapsulant encapsulates the die, the plurality of through vias and the at least one dummy structure. The redistribution structure is disposed on the die, the plurality of through vias, the at least one dummy structure and the encapsulant and electrically connected to the die and the plurality of through vias. The plurality of joint terminals are disposed on and electrically connected to the plurality of through vias. The second package is electrically connected to the first package through the plurality of joint terminals. In some embodiments, Young's modulus of the at least one dummy structure is greater than 10 GPa, and coefficient of thermal expansion of the at least one dummy structure is less than 44 ppm/° C. In some embodiments, a number of the at least one dummy structure is a multiple of four, and the multiple of four dummy structures are disposed adjacent to four corners of the die. In some embodiments, the first package further includes a first attach film disposed on the die and at least one second attach film disposed on the at least one dummy structure, wherein the first attach film and the redistribution structure are respectively located on opposite sides of the die, and the at least one second attach film and the redistribution structure are respectively located on opposite sides of the at least one dummy structure. In some embodiments, a thickness of the at least one dummy structure is smaller than a thickness of the plurality of through vias. In some embodiments, a distance between the at least one dummy structure and the die is equal to or greater than 60 μm and less than 300 μm. In some embodiments, a width of the at least one dummy structure along a first direction is WX, a width of the at least one dummy structure along a second direction is WY, and the package satisfies one of the following: 0.33*WX≤WY≤3*WX; and 0.33*WY≤WX≤3*WY. In some embodiments, a distance between the at least one dummy structure and an adjacent through via among the plurality of through vias is equal to or greater than 300 μm. In some embodiments, the package structure further includes an integrated passive device disposed on and electrically connected to the redistribution structure, wherein the integrated passive device and the die are located on opposite sides of the redistribution structure, respectively.

In accordance with alternative embodiments of the present disclosure, a method of manufacturing a package structure includes: forming a first package, including: forming a die, a plurality of through vias and at least one dummy structure on a carrier, wherein the plurality of through vias surround the die, the at least one dummy structure is disposed between the die and the plurality of through vias and adjacent to at least one corner of the die; encapsulating the die, the plurality of through vias and the at least one dummy structure by an encapsulant; forming a redistribution structure on the die, the plurality of through vias, the at least one dummy structure and the encapsulant; and separating the carrier from the first package; forming a plurality of joint terminals on the plurality of through vias; and stacking a second package on the first package, wherein the second package is electrically connected to the first package through the plurality of joint terminals. In some embodiments, the die is attached to the carrier through a first attach film, and the at least one dummy structure is attached to the carrier through at least one second attach film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
a die;
a plurality of through vias surrounding the die;
at least one dummy structure disposed between the die and the plurality of through vias and adjacent to at least one corner of the die;
an encapsulant encapsulating the die, the plurality of through vias and the at least one dummy structure; and
a redistribution structure disposed on the die, the plurality of through vias, the at least one dummy structure and the encapsulant and electrically connected to the die and the plurality of through vias.

2. The package according to claim 1, wherein Young's modulus of the at least one dummy structure is greater than 10 GPa, and coefficient of thermal expansion of the at least one dummy structure is less than 44 ppm/° C.

3. The package according to claim 1, wherein a number of the at least one dummy structure is a multiple of four, and the multiple of four dummy structures are disposed adjacent to four corners of the die.

4. The package according to claim 1, wherein a number of the at least one dummy structure is one, and the dummy structure is a ring structure surrounding the die.

5. The package according to claim 1, further comprising:
a first attach film disposed on the die, wherein the first attach film and the redistribution structure are located on opposite sides of the die, respectively; and
at least one second attach film disposed on the at least one dummy structure, wherein the at least one second attach film and the redistribution structure are located on opposite sides of the at least one dummy structure, respectively.

6. The package according to claim 1, wherein a thickness of the at least one dummy structure is smaller than a thickness of the plurality of through vias.

7. The package according to claim 1, wherein a distance between the at least one dummy structure and the die is equal to or greater than 60 μm and less than 300 μm.

8. The package according to claim 1, wherein a width of the at least one dummy structure along a first direction is WX, a width of the at least one dummy structure along a second direction is WY, and the package satisfies one of the following:
0.33*WX≤WY≤3*WX; and
0.33*WY≤WX≤3*WY.

9. The package according to claim 1, wherein a distance between the at least one dummy structure and an adjacent through via among the plurality of through vias is equal to or greater than 300 μm.

10. A package structure, comprising:
a first package, comprising:
a die;
a plurality of through vias surrounding the die;
at least one dummy structure disposed between the die and the plurality of through vias and adjacent to at least one corner of the die;
an encapsulant encapsulating the die, the plurality of through vias and the at least one dummy structure; and
a redistribution structure disposed on the die, the plurality of through vias, the at least one dummy structure and the encapsulant and electrically connected to the die and the plurality of through vias;
a plurality of joint terminals disposed on and electrically connected to the plurality of through vias; and
a second package electrically connected to the first package through the plurality of joint terminals.

11. The package structure according to claim 10, wherein Young's modulus of the at least one dummy structure is greater than 10 GPa, and coefficient of thermal expansion of the at least one dummy structure is less than 44 ppm/° C.

12. The package structure according to claim 10, wherein a number of the at least one dummy structure is a multiple of four, and the multiple of four dummy structures are disposed adjacent to four corners of the die.

13. The package structure according to claim 10, wherein the first package further comprises:
a first attach film disposed on the die, wherein the first attach film and the redistribution structure are located on opposite sides of the die, respectively; and
at least one second attach film disposed on the at least one dummy structure, wherein the at least one second attach film and the redistribution structure are located on opposite sides of the at least one dummy structure, respectively.

14. The package structure according to claim 10, wherein a thickness of the at least one dummy structure is smaller than a thickness of the plurality of through vias.

15. The package structure according to claim 10, wherein a distance between the at least one dummy structure and the die is equal to or greater than 60 μm and less than 300 μm.

16. The package structure according to claim 10, wherein a width of the at least one dummy structure along a first direction is WX, a width of the at least one dummy structure along a second direction is WY, and the package satisfies one of the following:
0.33*WX≤WY≤3*WX; and
0.33*WY≤WX≤3*WY.

17. The package structure according to claim 10, wherein a distance between the at least one dummy structure and an adjacent through via among the plurality of through vias is equal to or greater than 300 μm.

18. The package structure according to claim 10, further comprising:
an integrated passive device disposed on and electrically connected to the redistribution structure, wherein the integrated passive device and the die are located on opposite sides of the redistribution structure, respectively.

19. A method of manufacturing a package structure, comprising:
forming a first package, comprising:
forming a die, a plurality of through vias and at least one dummy structure on a carrier, wherein the plurality of through vias surround the die, the at least one dummy structure is disposed between the die and the plurality of through vias and adjacent to at least one corner of the die;
encapsulating the die, the plurality of through vias and the at least one dummy structure by an encapsulant;
forming a redistribution structure on the die, the plurality of through vias, the at least one dummy structure and the encapsulant; and
separating the carrier from the first package;
forming a plurality of joint terminals on the plurality of through vias; and
stacking a second package on the first package, wherein the second package is electrically connected to the first package through the plurality of joint terminals.

20. The method of manufacturing the package structure according to claim 19, wherein the die is attached to the carrier through a first attach film, and the at least one dummy structure is attached to the carrier through at least one second attach film.
